(19) United States
(12) Patent Application Publication
(10) Pub. No.: US 2026/0173386 A1
(43) Pub. Date: Jun. 18, 2026

(54) METHOD OF MANUFACTURING SEMICONDUCTOR DEVICE

(71) Applicant: Renesas Electronics Corporation, Tokyo (JP)

(72) Inventors: Ryu KAWANO, Tokyo (JP); Toshiya SAITO, Tokyo (JP)

(21) Appl. No.: 19/368,164

(22) Filed: Oct. 24, 2025

(30) Foreign Application Priority Data
Dec. 17, 2024 (JP) 2024-220866

(51) Int. Cl. H10B 43/30

(52) U.S. Cl. CPC H10B 43/30

(57) ABSTRACT

A method of manufacturing a semiconductor device includes: a step of forming a liner film so as to cover a first gate electrode and a second gate electrode; a step of forming an insulating film on the liner film; a step of exposing the liner film positioned on each of the first gate electrode and the second gate electrode by performing anisotropic dry etching to the insulating film, and forming a buried layer between the first gate electrode and the second gate electrode; a step of forming an interlayer insulating film on the buried layer; and a step of forming a contact hole in the interlayer insulating film, the buried layer and the liner film, and forming a plug electrode in the contact hole.

### CROSS-REFERENCE TO RELATED APPLICATION

The disclosure of Japanese Patent Application No. 2024-220866 filed on December 17, 2024, including the specification, drawings and abstract is incorporated herein by reference in its entirety.

### BACKGROUND

The present invention relates to a method of manufacturing a semiconductor device, and relates to a technique effectively applied to, for example, a method of manufacturing a semiconductor device including a flash memory.

An electrically erasable and programmable read only memory (EEPROM) has been widely used as an electrically writable and erasable non-volatile memory. There is an example of use of a split-gate type MONOS (metal oxide nitride oxide semiconductor) memory as the EEPROM embedded in a microcomputer.

There is disclosed technique listed below.

[Patent Document 1] Japanese Unexamined Patent Application Publication No. 2018-56222

The Patent Document 1 describes a technique related to the split-gate type MONOS (metal oxide nitride oxide semiconductor) memory.

### SUMMARY

The inventors of the present application have confirmed the following problems in a semiconductor device including a plurality of split-gate type MONOS memories arranged in a matrix pattern.

A split-gate type MONOS memory includes: a drain region and a source region that are formed in a semiconductor substrate; a control gate electrode formed on the semiconductor substrate via a gate insulating film; and a memory gate electrode formed on the semiconductor substrate via a charge holding film. An interlayer insulating film that fills a gap between adjacent control gate electrodes is formed on the semiconductor substrate, and a plug electrode is formed in the interlayer insulating film. The plug electrode electrically connects the drain region and a bit line. A plurality of plug electrodes are arranged at predetermined intervals between the adjacent control gate electrodes along an extending direction of the control gate electrodes.

By miniaturization of the semiconductor device, a distance between the adjacent control gate electrodes is decreased. It has been confirmed that voids are formed in the interlayer insulating film between the adjacent control gate electrodes. By the formation of the voids between the adjacent plug electrodes, the adjacent bit lines are short-circuited. This is because a metal layer is also formed in the voids by a plug-electrode forming step. Note that the Patent Document 1 has also discussed this problem.

In such a split-gate type MONOS memory, a technique for preventing the short-circuit between the adjacent bit lines has been awaited. That is, a technique for improving reliability of the semiconductor device has been awaited.

Other problems and novel characteristics will become apparent from the description of the present specification and the accompanying drawings.

A method of manufacturing a semiconductor device according to one embodiment includes: a step of forming a first insulating film so as to cover a first gate electrode and a second gate electrode; and a step of forming a second insulating film on the first insulating film. The method of manufacturing the semiconductor device further includes a step of exposing the first insulating film positioned on each of the first gate electrode and the second gate electrode by performing anisotropic dry etching to the second insulating film, and of forming a buried layer between the first gate electrode and the second gate electrode. The method of manufacturing the semiconductor device further includes: a step of forming a third insulating film on the buried layer; and a step of forming a contact hole in each of the third insulating film, the buried layer, and the first insulating film, and of forming a conductive layer in the contact hole.

According to the embodiment, reliability of the semiconductor device can be improved.

### BRIEF DESCRIPTIONS OF THE DRAWINGS

FIG. 1 is a cross-sectional view illustrating principal parts of a semiconductor device according to one embodiment.

FIG. 2 is a plan view illustrating principal parts of the semiconductor device according to the embodiment.

FIG. 3 is a cross-sectional view illustrating a step of manufacturing the semiconductor device according to the embodiment.

FIG. 4 is a cross-sectional view illustrating a step of manufacturing the semiconductor device continued from FIG. 3.

FIG. 5 is a cross-sectional view illustrating a step of manufacturing the semiconductor device continued from FIG. 4.

FIG. 6 is a cross-sectional view illustrating a step of manufacturing the semiconductor device continued from FIG. 5.

FIG. 7 is a cross-sectional view illustrating a step of manufacturing the semiconductor device continued from FIG. 6.

FIG. 8 is a cross-sectional view illustrating a step of manufacturing the semiconductor device continued from FIG. 7.

FIG. 9 is a cross-sectional view illustrating a step of manufacturing the semiconductor device continued from FIG. 8.

FIG. 10 is a cross-sectional view illustrating a step of manufacturing the semiconductor device continued from FIG. 9.

FIG. 11 is a cross-sectional view illustrating a step of manufacturing the semiconductor device continued from FIG. 10.

FIG. 12 is a cross-sectional view illustrating a step of manufacturing the semiconductor device continued from FIG. 11.

FIG. 13 is a cross-sectional view illustrating a step of manufacturing the semiconductor device continued from FIG. 12.

FIG. 14 is a cross-sectional view illustrating a step of manufacturing a semiconductor device according to a first modification example.

FIG. 15 is a cross-sectional view illustrating a step of manufacturing a semiconductor device according to a second modification example.

### DETAILED DESCRIPTION

The same components are denoted with the same reference symbols throughout all the drawings for describing the embodiments, and the repetitive description thereof will be omitted.

In the following embodiments, a term “N-type” means an “N” conductive type, and a term “P-type” means a “P” conductive type. A term “P-type impurity region” can be rephrased as a term “P-type semiconductor region”, and a term “N-type impurity region” can be rephrased as a term “N-type semiconductor region”.

An “X” direction and a “Y” direction are along a main surface of a semiconductor substrate, and are orthogonal to each other.

### Embodiment

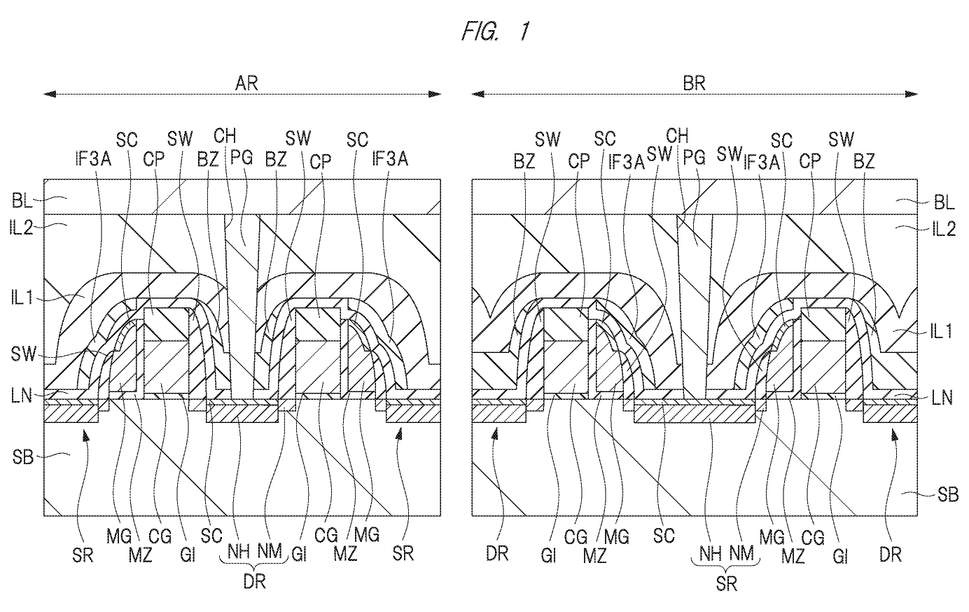

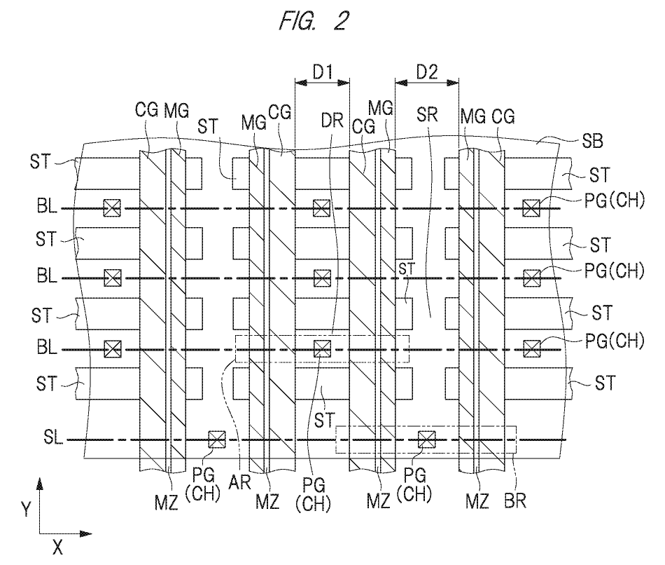

A semiconductor device according to the present embodiment includes a plurality of memory cells. Each of the memory cells is made of a split-gate type MONOS memory, and a memory cell array is made of a plurality of the memory cells. The plurality of memory cells that configure the memory cell array are arranged in a matrix pattern in the X direction and the Y direction on the main surface of a semiconductor substrate SB. FIG. 2 is a plan view of the memory cell array. FIG. 1 is a cross-sectional view of the semiconductor device along a bit line BL at a region AR and a cross-sectional view of the semiconductor device along a source line SL at a region BR.

As illustrated in FIG. 2, each of a plurality of control gate electrodes CG and a plurality of memory gate electrodes MG extends in the Y direction on the main surface of the semiconductor substrate SB. Each of a plurality of bit lines BL and a plurality of source lines SL extends in the X direction. A drain region DR in a memory cell is electrically connected to the bit line BL via a plug electrode PG. A source region SR in the memory cell is electrically connected to the source line SL via a plug electrode PG. In plan view, the drain region DR is arranged between two adjacent control gate electrodes CG in the X direction, and is arranged between two adjacent shallow trench isolators ST in the Y direction. In plan view, the source region SR is arranged between two adjacent memory gate electrodes MG in the X direction, and extends in the Y direction.

At the region AR, two adjacent memory cells in the X direction share the drain region DR, and are symmetrical across the drain region DR. At the region BR, two adjacent memory cells in the X direction share the source region SR, and are symmetrical across the source region SR. In order to extend the source region SR in the Y direction, the source region SR is arranged between two adjacent shallow trench isolators ST in the X direction. Thus, in the X direction, the distance D2 between two adjacent memory gate electrodes MG is larger than the distance D1 between two adjacent control gate electrodes CG (D2 > D1).

As illustrated in FIG. 1, the memory cell includes the drain region DR, the source region SR, the gate insulating film GI, the control gate electrode CG, an insulating film MZ, the memory gate electrode MG, and a cap insulating film CP. The drain region DR and the source region SR are arranged with a predetermined interval therebetween in the semiconductor substrate SB. A channel forming region is positioned between the drain region DR and the source region SR. The control gate electrode CG and the memory gate electrode MG are formed on the channel forming region. The control gate electrode CG is formed on the main surface of the semiconductor substrate SB via the gate insulating film GI. The memory gate electrode MG is formed on the main surface of the semiconductor substrate SB via the insulating film MZ. The insulating film MZ is L-shaped in cross-sectional view, and is arranged between the control gate electrode CG and the memory gate electrode MG and between the memory gate electrode MG and the main surface of the semiconductor substrate SB. The insulating film MZ is formed between the semiconductor substrate SB and the memory gate electrodes MG, but an insulating film different from the insulating film MZ may be formed between the control gate electrode CG and the memory gate electrode MG. The control gate electrode CG is arranged between the drain region DR and the memory gate electrode MG, and the memory gate electrode MG is arranged between the control gate electrode CG and the source region SR. The cap insulating film CP is formed on the control gate electrode CG. A stacked structure including the control gate electrode CG and the cap insulating film CP is referred to as “gate electrode.” Each of the drain region DR and the source region SR includes an N-type impurity region NM and an N-type impurity region NH. A silicide layer SC is formed on the drain region DR. And, a silicide layer SC is formed on the source region SR. Further, a silicide layer SC is formed on the memory gate electrode MG.

The main surface of the semiconductor substrate SB and the memory cell are covered with a liner film LN, an interlayer insulating film IL1, and an interlayer insulating film IL2. The liner film LN is formed on the gate electrode and the memory gate electrode MG so as to cover the memory cell. The interlayer insulating film IL1 is formed on the liner film LN. The interlayer insulating film IL2 is formed on the interlayer insulating film IL1.

At the region AR, the bit line BL is electrically connected to the drain region DR via the plug electrode PG. The liner film LN, a buried layer BZ, the interlayer insulating film IL1, and the interlayer insulating film IL2 are formed on the drain region DR at a region between the two adjacent gate electrodes. The buried layer BZ positioned on the drain region DR covers the liner film LN and is formed between the liner film LN and the interlayer insulating film IL1. The plug electrode PG is formed in a contact hole CH penetrating through the interlayer insulating film IL2, the interlayer insulating film IL1, the buried layer BZ and the liner film LN. The bit line BL is formed on the interlayer insulating film IL2. Note that the liner film LN positioned on the gate electrode is in contact with the interlayer insulating film IL1. That is, the buried layer BZ is not present on the liner film LN positioned on the gate electrode.

At the region BR, the source line SL is electrically connected to the source region SR via the plug electrode PG. The liner film LN, the interlayer insulating film IL1, and the interlayer insulating film IL2 are formed on the source region SR at a region between the two adjacent memory gate electrodes MG. The plug electrode PG is formed in a contact hole CH that penetrates through the interlayer insulating film IL2, the interlayer insulating film IL1 and the liner film LN. As described above, two memory cells share the source region SR, and are symmetric across the source region SR. The two memory cells are arranged on both sides of the plug electrode PG connected to the source region SR. Two insulting films IF3A are formed on the source region SR, and the plug electrode PG is arranged between the two insulating films IF3A. One insulating film IF3A is selectively formed on the liner film LN formed on the sidewall of the memory gate electrode MG of one memory cell. The other insulating film IF3A is selectively formed on the liner film LN formed on the sidewall of the memory gate electrode MG of the other memory cell. The two insulating films IF3A on the source region SR are away from each other. As described later, the insulating films IF3A are formed by a step of forming the buried layer BZ. The distance D2 between the two adjacent memory gate electrodes MG at the region BR is longer than the distance D1 between the two adjacent gate electrodes at the region AR. Thus, the two insulating films IF3A on the source region SR are formed away from each other.

Next, a method of manufacturing the semiconductor device according to the present embodiment will be described with reference to FIGS. 1 and 3 to 13.

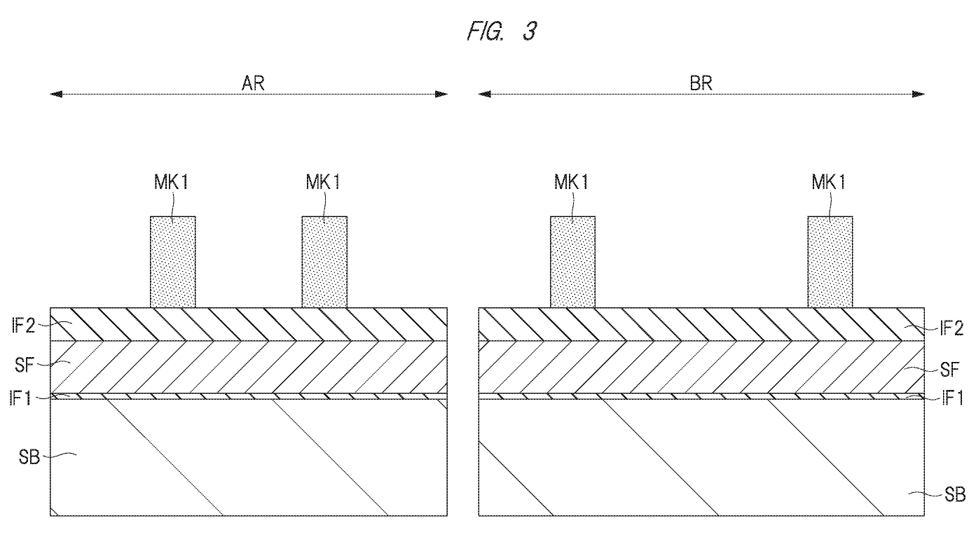

First, the insulating film IF1, a silicon film SF, and the insulating film IF2 are formed on the main surface of the semiconductor substate SB as illustrated in FIG. 3. The semiconductor substrate SB is made of, for example, P-type single crystal silicon. The insulating film IF1 is made of, for example, a silicon oxide film. The insulating film IF1 may include a silicon oxide film and a silicon nitride film formed on the silicon oxide film. The silicon film SF is made of, for example, a polycrystal silicon film, and the polycrystal silicon film is deposited on the insulating film IF1 by using a CVD method. The insulating film IF2 is made of, for example, a silicon nitride film, and the silicon nitride film is deposited on the silicon film SF by using a CVD method.

Next, a mask layer MK1 having a desired pattern is formed on the insulating film IF2 as illustrated in FIG. 3. The mask layer MK1 is made of, for example, a photoresist film. The mask layer MK1 has a pattern corresponding to the gate electrode.

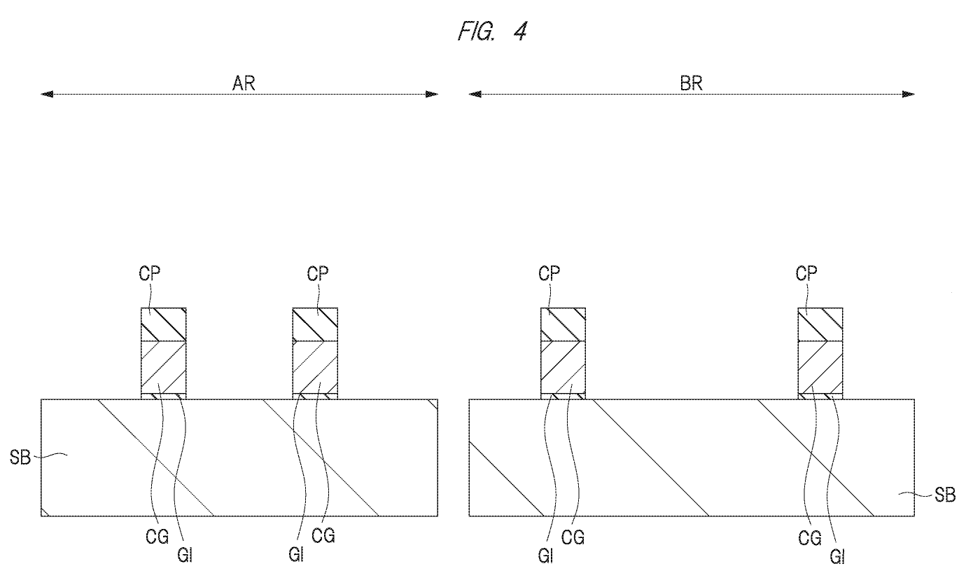

Next, the insulating film IF2, the silicon film SF, and the insulating film IF1, that are exposed from the mask layer MK1, are removed by using a dry etching method as illustrated in FIG. 4. The gate electrode, that is made of the control gate electrode CG and the cap insulating film CP formed on the control gate electrode CG, is formed on the gate insulating film G1.

At the region AR, the first gate electrode and the second gate electrode are formed in an order from left to right on the main surface of the semiconductor substrate SB. The first gate electrode has a first sidewall and a second sidewall opposite to the first sidewall, and each of the first sidewall and the second sidewall extends in the Y direction. The second gate electrode has a third sidewall and a fourth sidewall opposite to the third sidewall, and each of the third sidewall and the fourth sidewall extends in the Y direction. The second sidewall of the first gate electrode faces the third sidewall of the second gate electrode.

At the region BR, a third gate electrode and a fourth gate electrode are formed in an order from left to right on the main surface of the semiconductor substrate SB. The third gate electrode has a fifth sidewall and a sixth sidewall opposite to the fifth sidewall, and each of the fifth sidewall and the sixth sidewall extends in the Y direction. The fourth gate electrode has a seventh sidewall and an eighth sidewall opposite to the seventh sidewall, and each of the seventh sidewall and the eighth sidewall extends in the Y direction. The sixth sidewall of the third gate electrode faces the seventh sidewall of the fourth gate electrode.

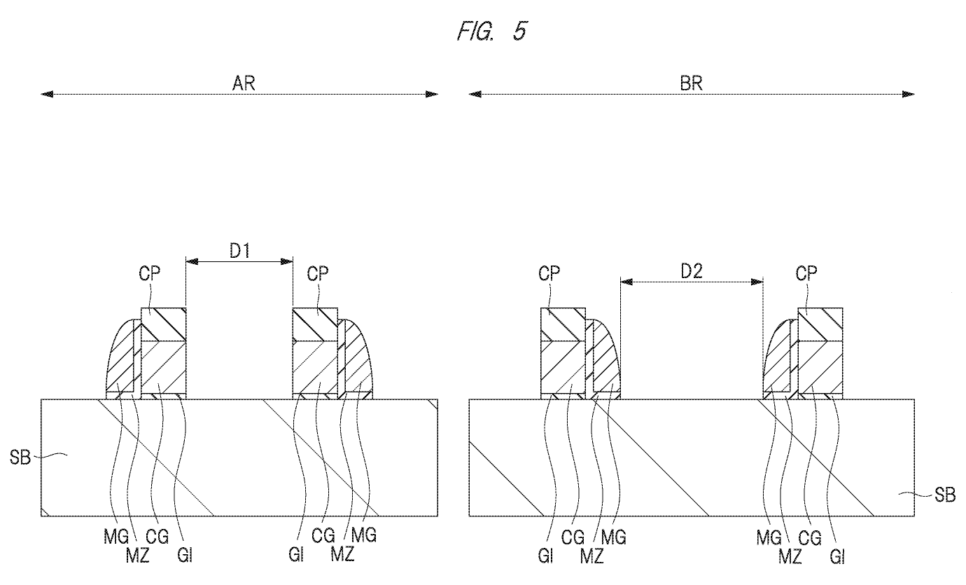

Next, the insulating film (also referred to as charge holding film) MZ and the memory gate electrode MG are formed on the main surface of the semiconductor substrate SB as illustrated in FIG. 5. The insulating film MZ includes, for example, a silicon oxide film, a silicon nitride film, and a silicon oxide film. The memory gate electrode MG is made of, for example, a polycrystal silicon film.

At the region AR, a first memory gate electrode MG is formed on each of the first sidewall of the first gate electrode and the main surface of the semiconductor substrate SB via the insulating film MZ. A second memory gate electrode MG is formed on each of the fourth sidewall of the second gate electrode and the main surface of the semiconductor substrate SB via the insulating film MZ.

At the region BR, a third memory gate electrode MG is formed on each of the sixth sidewall of the third gate electrode and the main surface of the semiconductor substrate SB via the insulating film MZ. A fourth memory gate electrode MG is formed on each of the seventh sidewall of the fourth gate electrode and the main surface of the semiconductor substrate SB via the insulating film MZ.

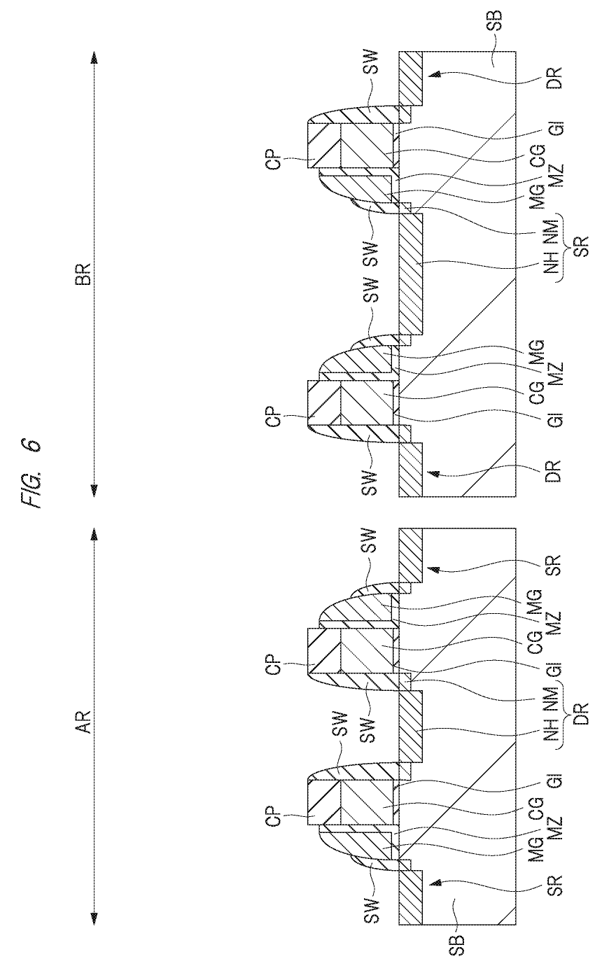

Next, the drain region DR and the source region SR are formed in the semiconductor substrate SB as illustrated in FIG. 6. At the region AR, the N-type impurity region NM is formed in the semiconductor substrate SB at a region between the first gate electrode and the second gate electrode in plan view. At the region BR, the N-type impurity region NM is formed in the semiconductor substrate SB at a region between the third memory gate electrode MG and the fourth memory gate electrode MG in plan view. The N-type impurity region NM is formed by using an ion implantation method or the like. That is, an N-type impurity such as arsenic (As) or phosphorus (P) is introduced into the semiconductor substrate SB.

Next, at the region AR, sidewall insulating films SW are formed on each of the second sidewall of the first gate electrode and the third sidewall of the second gate electrode, respectively. At the region BR, sidewall insulating films SW are formed on each of the sidewall of the third memory gate electrode MG and the sidewall of the fourth memory gate electrode MG, respectively.

Next, at the region AR, the N-type impurity region NH is formed in the semiconductor substrate SB at a region between the sidewall insulating film SW on the second sidewall of the first gate electrode and the sidewall insulating film SW on the third sidewall of the second gate electrode in plan view. At the region BR, the N-type impurity region NH is formed in the semiconductor substrate SB at a region between the sidewall insulating film SW on the sidewall of the third memory gate electrode MG and the sidewall insulating film SW on the sidewall of the fourth memory gate electrode MG in plan view. The N-type impurity region NH is formed by using an ion implantation method or the like. That is, an N-type impurity such as arsenic (As) or phosphorus (P) is introduced into the semiconductor substrate SB. The impurity concentration of the N-type impurity region NH is higher than the impurity concentration of the N-type impurity region NM.

In the above steps, at the region AR, the drain region DR including the N-type impurity region NM and the N-type impurity region NH is formed in the semiconductor substrate SB at the region between the first gate electrode and the second gate electrode in plan view. At the region BR, the source region SR including the N-type impurity region NM and the N-type impurity region NH is formed in the semiconductor substrate SB at the region between the third memory gate electrode MG and the fourth memory gate electrode MG in plan view.

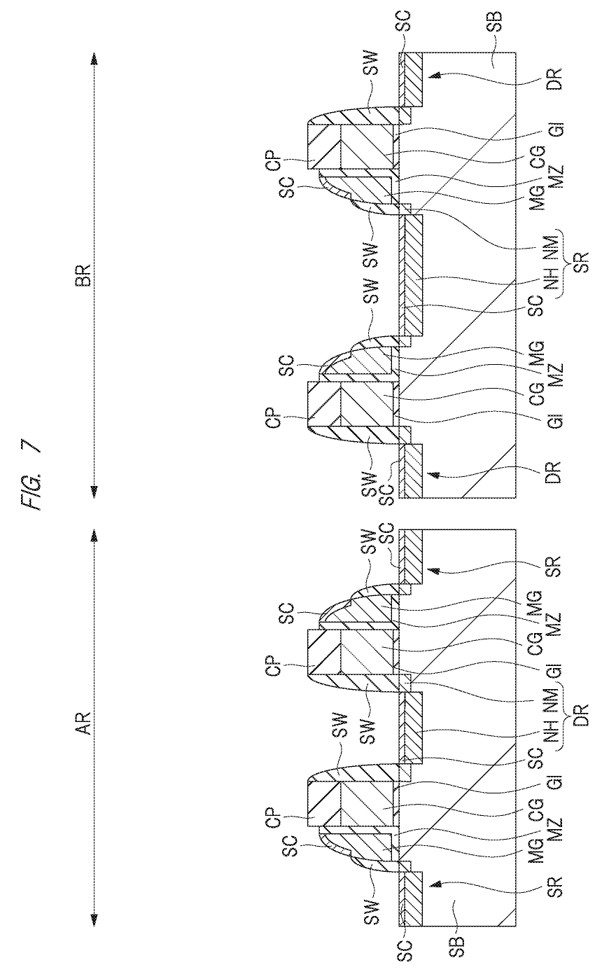

Next, the silicide layers SC are formed as illustrated in FIG. 7. At the region AR, the silicide layers SC are formed on each of the drain region DR, the first memory gate electrode MG, and the second memory gate electrode MG. At the region BR, the silicide layers SC are formed on each of the source region SR, the third memory gate electrode MG, and the fourth memory gate electrode MG. The silicide layer SC is made of, for example, an alloy film of nickel (Ni) and platinum (Pt).

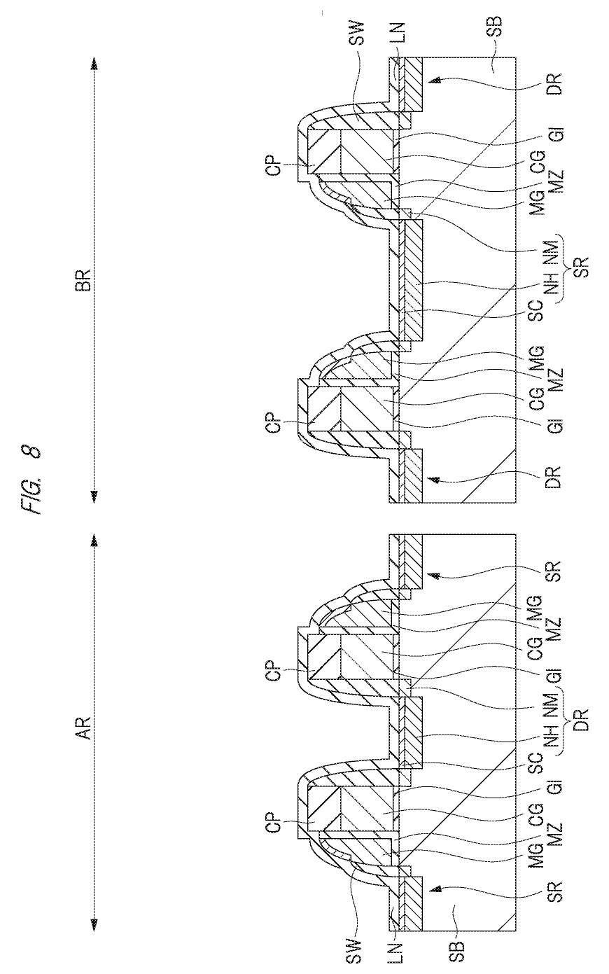

Next, the liner film LN is formed on the main surface of the semiconductor substrate SB so as to cover the memory cell as illustrated in FIG. 8. The liner film LN covers the first gate electrode, the second gate electrode, the third gate electrode, and the fourth gate electrode. Further, the liner film LN covers the first memory gate electrode, the second memory gate electrode, the third memory gate electrode, and the fourth memory gate electrode. The liner film LN is made of an insulating film such as silicon nitride film, and is deposited on the main surface of the semiconductor substrate SB by using a CVD method.

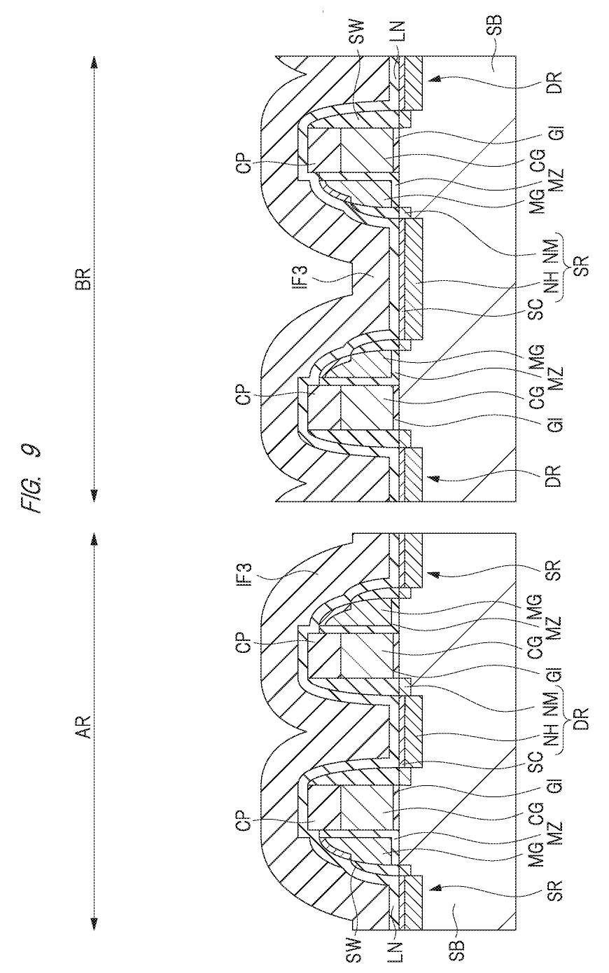

Next, the insulating film IF3 is formed on the liner film LN as illustrated in FIG. 9. The insulating film IF3 is made of a silicon oxide film, and is deposited on the liner film LN by using a CVD method. An O₃-tetraethyl orthosilicate (TEOS) film with excellent step coverage is preferably used as the insulating film IF3.

The region AR will be described first. A gap between the first gate electrode and the second gate electrode that are adjacent to each other is filled with the insulating film IF3. That is, at the region between the first gate electrode and the second gate electrode, the upper surface of the insulating film IF3 is equal to or higher than the upper surface of the cap insulating film CP relative to the main surface of the semiconductor substrate SB. At the region between the first gate electrode and the second gate electrode, the lowest portion of the upper surface of the insulating film IF3 is equal to the upper surface of the cap insulating film CP or higher than the upper surface of the cap insulating film CP. The thickness T2 of the insulating film IF3 with which the region between the first gate electrode and the second gate electrode is filled is expressed by the following expression.

[Numerical Expression 1] T2 ≥ D1/2 – T1

In the numerical expression 1, a term “D1” represents the distance between the first gate electrode and the second gate electrode, and a term “T1” represents the thickness of the liner film LN positioned on the first gate electrode. A term “T2” represents the thickness of the insulating film IF3 positioned on the first gate electrode. Note that the thickness T1 of the liner film LN is made smaller than the thickness T2 of the insulating film IF3 (T1 < T2) in order to fill the region between the first gate electrode and the second gate electrode with the insulating film IF3.

As described above, the region between the first gate electrode and the second gate electrode is filled with the insulating film IF3, and thus, the insulating film IF3 at the region between the first gate electrode and the second gate electrode has the thickness T3. The thickness T3 of the insulating film IF3 at the region between the first gate electrode and the second gate electrode is larger than the thickness T2 of the insulating film IF3 positioned on the first gate electrode or the second gate electrode (T3 > T2). In this case, the thickness T1, the thickness T2, and the thickness T3 are thicknesses in the vertical direction relative to the main surface of the semiconductor substrate SB.

To the contrary, at the region BR, the region between the third memory gate electrode and the fourth memory gate electrode that are adjacent to each other is not filled with the insulating film IF3. At the region between the third memory gate electrode and the fourth memory gate electrode, the upper surface of the insulating film IF3 has a part lower than the upper surface of the cap insulating film CP relative to the main surface of the semiconductor substrate SB. That is, the thickness of the part of the insulating film IF3 positioned on the source region SR is almost equal to the thickness T2 of the insulating film IF3 on the third gate electrode or the fourth gate electrode.

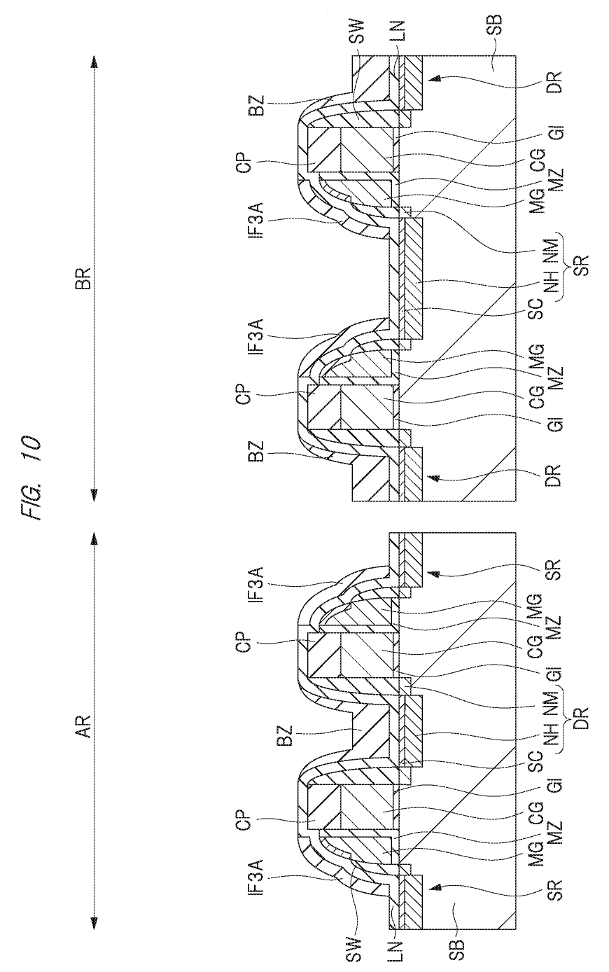

Next, anisotropic dry etching is performed to the insulating film IF3 to form the buried layer BZ and the insulating film IF3A as illustrated in FIG. 10.

The region AR will be described. In the step of performing anisotropic dry etching to the insulating film IF3, the insulating film IF3 positioned on the first gate electrode and the second gate electrode is etched to expose the liner film LN. To the contrary, the buried layer BZ covering the liner film LN is formed at the region between the first gate electrode and the second gate electrode. This is because the thickness T3 of the insulating film IF3 at the region between the first gate electrode and the second gate electrode is larger than the thickness T2 of the insulating film IF3 on the first gate electrode or the second gate electrode as illustrated in FIG. 9. The buried layer BZ has a first part, a second part, and a third part in cross-sectional view. The first part is formed on the liner film LN along the main surface of the semiconductor substrate SB as illustrated in FIG. 10. The second part is formed along the liner film LN on the sidewall of the first gate electrode. The third part is formed along the liner film LN on the sidewall of the second gate electrode. The second part is connected to one end of the first part, and the third part is connected to the other end of the first part. Each of the second part and the third part extends in the vertical direction relative to the main surface of the semiconductor substrate SB. That is, by the anisotropic dry etching step, the buried layer BZ that is positioned on the drain region DR and is concave in cross-sectional view is formed on the liner film LN.

To the contrary, at the region BR, the region between the third memory gate electrode MG and the fourth memory gate electrode MG that are adjacent to each other is not filled with the insulating film IF3 as illustrated in FIG. 9, and thus, the buried layer BZ is not formed. The insulating film IF3A is formed on the liner film LN covering the sidewall of the third memory gate electrode MG as illustrated in FIG. 10. The insulating film IF3A is formed on the liner film LN covering the sidewall of the fourth memory gate electrode MG. The two insulating films IF3A formed between the third memory gate electrode MG and the fourth memory gate electrode MG are away from each other. That is, a part of the liner film LN positioned on the source region SR is exposed from the insulating films IF3A.

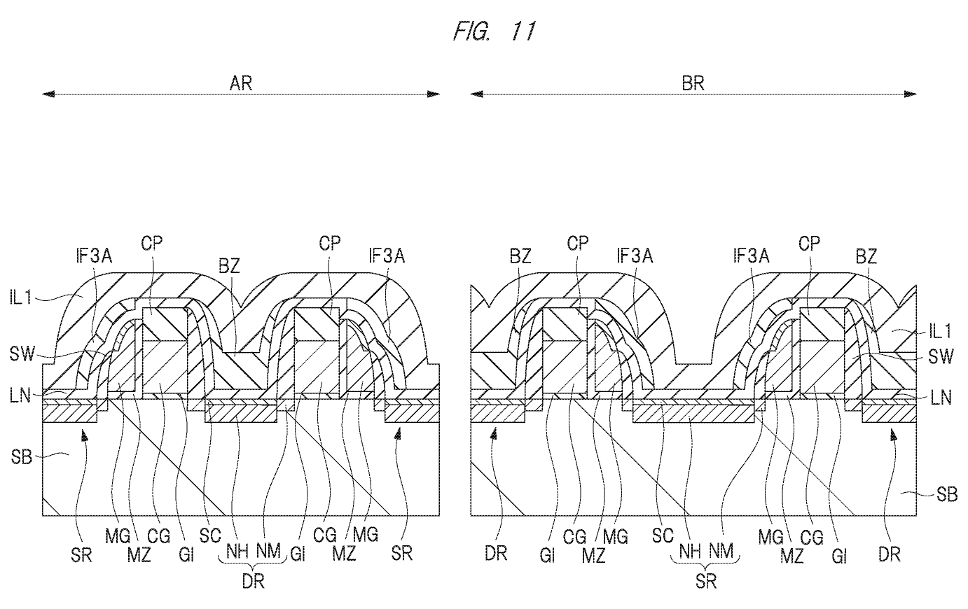

Next, the interlayer insulating film IL1 is formed on the semiconductor substrate SB so as to cover the memory cell, the liner film LN, the buried layer BZ, and the insulating films IF3A as illustrated in FIG. 11. The interlayer insulating film IL1 is made of a silicon oxide film, and is deposited on each of the liner film LN and the buried layer BZ by using a CVD method. An O₃-TEOS film with excellent step coverage is preferably used as the interlayer insulating film IL1.

At the region AR, the buried layer BZ is formed at the region between the first gate electrode and the second gate electrode. Thus, the region between the first gate electrode and the second gate electrode can be filled with the interlayer insulating film IL1 without the formation of the voids in the interlayer insulating film IL1 positioned on the drain region DR.

At the region BR, the distance between the third memory gate electrode MG and the fourth memory gate electrode MG is larger than the distance between the first gate electrode and the second gate electrode, and thus, no void is formed in the interlayer insulating film IL1 positioned on the source region SR.

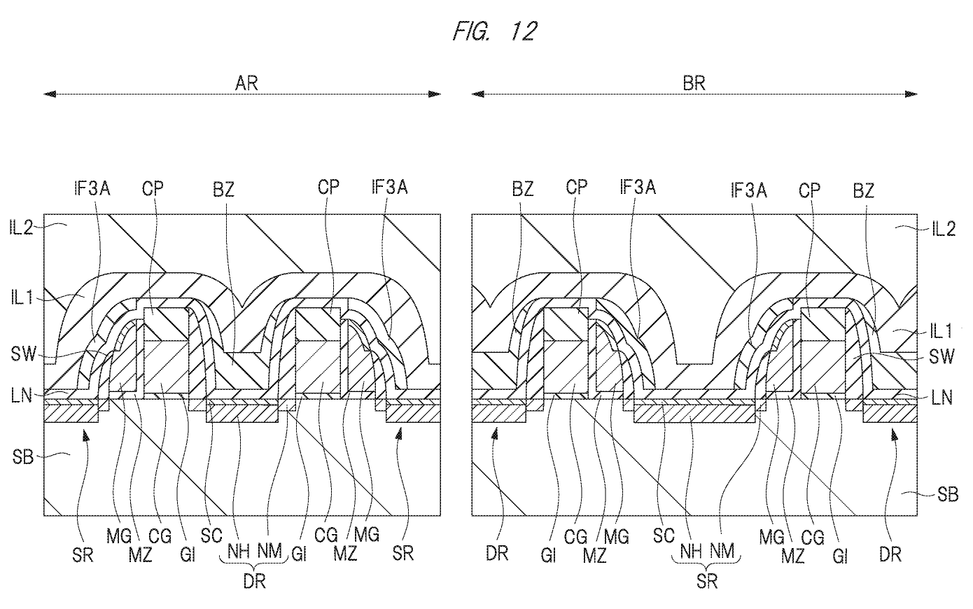

Next, the interlayer insulating film IL2 is formed on the interlayer insulating film IL1 as illustrated in FIG. 12. The interlayer insulating film IL2 is made of a silicon oxide film, and is deposited on the interlayer insulating film IL1 by using a CVD method. A TEOS film with more excellent mechanical property than that of the interlayer insulating film IL1 is preferably used as the interlayer insulating film IL2. Then, chemical mechanical polishing (CMP) is performed to the interlayer insulating film IL2 to flatten the upper surface of the interlayer insulating film IL2.

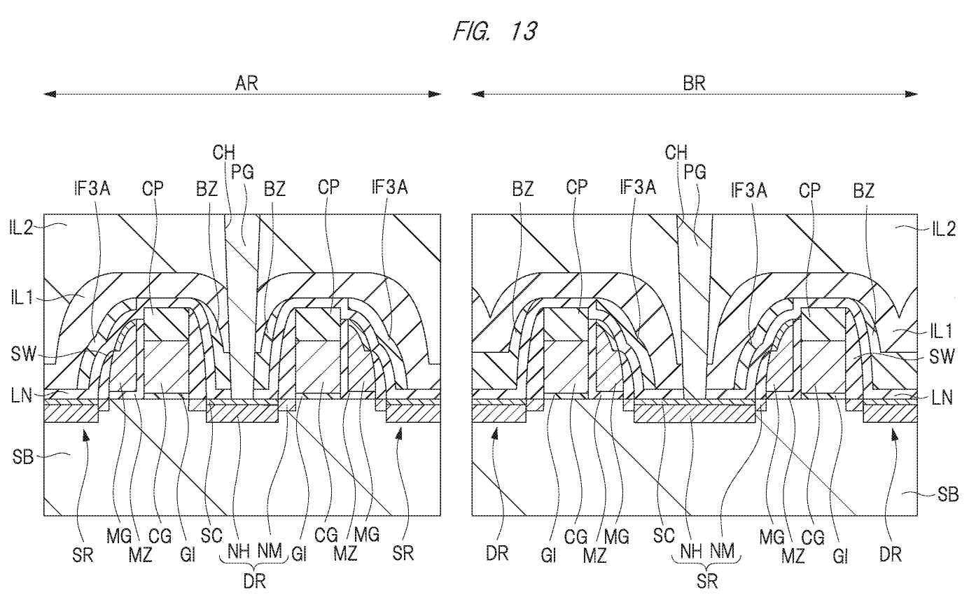

Next, the plug electrodes PG are formed as illustrated in FIG. 13. At the region AR, the interlayer insulating film IL2, the interlayer insulating film IL1, the buried layer BZ, and the liner film LN are etched. Then, the contact hole CH penetrating through the interlayer insulating film IL2, the interlayer insulating film IL1, the buried layer BZ and the liner film LN is formed. The contact hole CH is formed on the drain region DR, and the plug electrode PG is formed in the contact hole CH. The plug electrode PG is in contact with the silicide layer SC formed on the upper surface of the drain region DR. At the region BR, the interlayer insulating film IL2, the interlayer insulating film IL1, and the liner film LN are etched. Then, the contact hole CH penetrating through the interlayer insulating film IL2, the interlayer insulating film IL1 and the liner film LN is formed. The contact hole CH is formed on the source region SR, and the plug electrode PG is formed in the contact hole CH. The plug electrode PG is in contact with the silicide layer SC formed on the upper surface of the source region SR. The plug electrode PG includes a barrier conductor film and a main conductor film. The barrier conductor film is made of, for example, a titanium film, a titanium nitride film, or a stacked film of a titanium film and a titanium nitride film on the titanium film. The main conductor film is formed on the barrier conductor film, and is made of, for example, tungsten (W).

Next, a wiring layer including the bit line BL and the source line SL is formed on the interlayer insulating film IL2 as illustrated in FIG. 1. The wiring layer is made of, for example, a copper (Cu) film or an aluminum (Al) film. The bit line BL is electrically connected to the drain region DR via the plug electrode PG. The source line SL is electrically connected to the source region SR via the plug electrode PG.

Note that the second gate electrode at the region AR and the third gate electrode at the region BR are the same gate electrode as each other as illustrated in FIG. 2. The second gate electrode and the third gate electrode may be different gate electrodes from each other. The second memory gate electrode MG at the region AR and the third memory gate electrode MG at the region BR are the same memory gate electrode MG as each other as illustrated in FIG. 2. The second memory gate electrode MG and the third memory gate electrode MG may be different memory gate electrodes MG from each other.

The method of manufacturing the semiconductor device according to the present embodiment has the following features.

The buried layer BZ is formed on the liner film LN at the region between the first gate electrode and the second gate electrode, and then, the region between the first gate electrode and the second gate electrode is filled with the interlayer insulating film IL1. Since the buried layer BZ is formed before forming the interlayer insulating film IL1, the region being on the drain region DR and being between the first gate electrode and the second gate electrode can be filled with the interlayer insulating film IL1 with no void. Thus, the short-circuiting between the plurality of plug electrodes PG formed in the interlayer insulating film IL1 can be prevented.

### <First Modification Example>

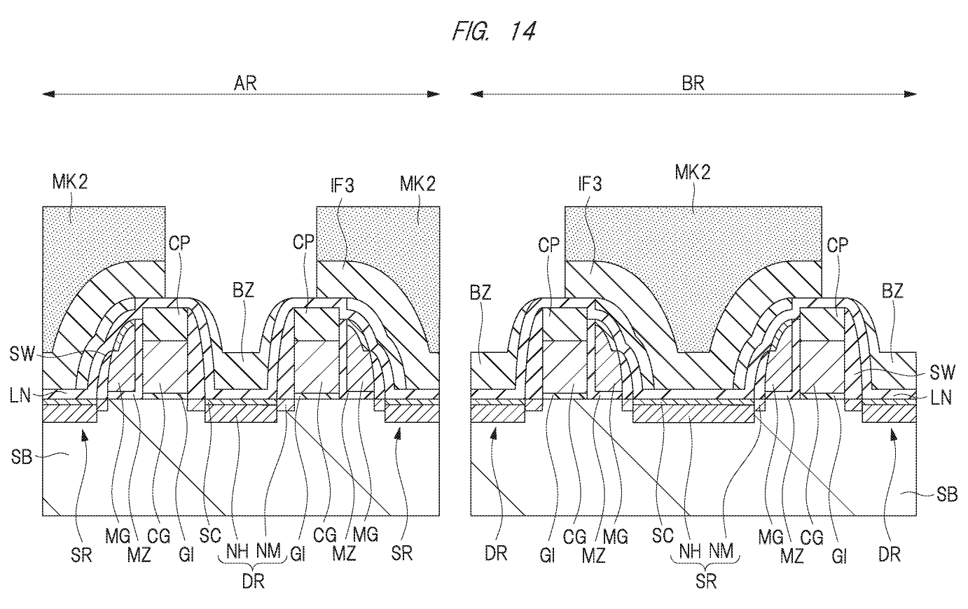

A first modification example is a modification example related to FIG. 10 of the above embodiment. As illustrated in FIG. 14, after the insulating film IF3 is formed and then a mask layer MK2 is formed, anisotropic dry etching is performed to the insulating film IF3. At the region AR, the mask layer MK2 has an opening portion exposing the buried layer BZ positioned on the drain region DR, the liner film LN positioned on a part of the first gate electrode, and the liner film LN positioned on a part of the second gate electrode. The drain region DR is arranged in the opening portion between a part of the first gate electrode and a part of the second gate electrode in plan view. By the anisotropic dry etching step, the insulating films IF3 positioned on each of a part of the first gate electrode in the opening portion and a part of the second gate electrode in the opening portion in plan view are removed to expose the liner film LN. Further, by the anisotropic dry etching step, the buried layer BZ similar to that in the above embodiment is formed at the region between the first gate electrode and the second gate electrode.

To the contrary, at the region BR, the insulating film IF3 on the source region SR is covered with the mask layer MK2, and thus, the liner film LN on the source region SR is not exposed. That is, the liner film LN on the source region SR has a sufficient thickness for function as an etching stopper. In the above embodiment, the thickness of the liner film LN may be decreased by the exposure of the liner film LN on the source region SR. The decrease in the thickness of the liner film LN does not cause the liner film LN to function as the etching stopper in the etching step in forming the contact hole CH.

In the first modification example, the decrease in the thickness of the liner film LN on the source region SR can be prevented. Thus, in forming the contact hole CH on the source region SR, a problem that is penetration of the contact hole CH through the source region SR can be prevented. That is, short-circuiting between the source region SR and the semiconductor substrate SB can be prevented.

### <Second Modification Example>

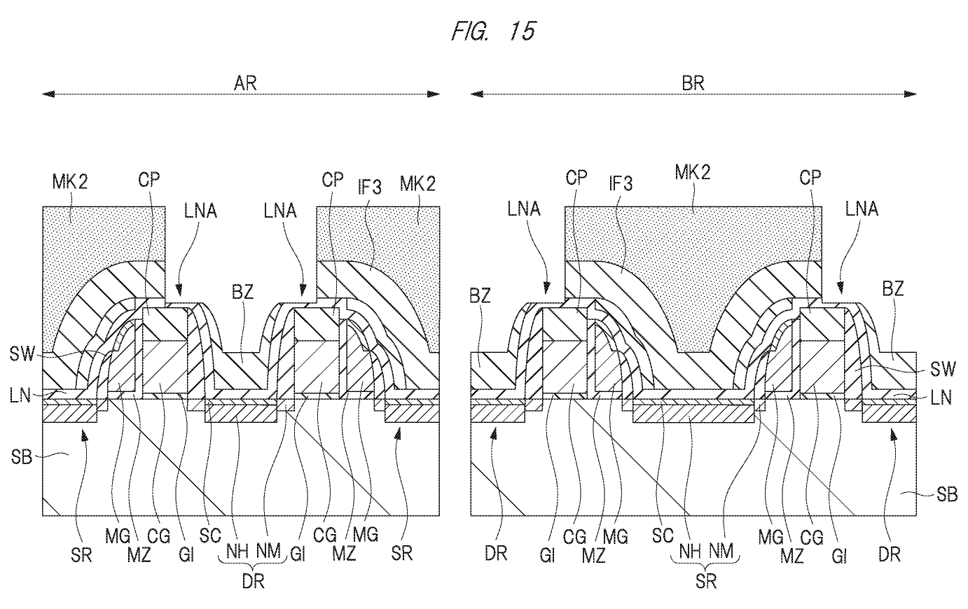

A second modification example is a modification example related to the first modification example. A difference from the first modification example is the thicknesses of the liner films LN on each of the first gate electrode and the second gate electrode. The liner film LN on the first gate electrode will be described herein, but the liner film LN on the second gate electrode is also similarly processed. In the anisotropic dry etching step for the insulating film IF3 in the first modification example, the anisotropic dry etching is finished when the liner film LN on the first gate electrode is exposed. In the second modification example, the anisotropic dry etching is continued even after the insulating film IF3 is completely etched to expose the liner film LN on the first gate electrode as illustrated in FIG. 15. In the anisotropic dry etching step, the thickness of the liner film LN positioned in the opening portion of the mask layer MK2 is decreased. That is, a thickness of a liner film LNA exposed from the mask layer MK2 is made smaller than the thickness of the liner film LN covered with the mask layer MK2. By the anisotropic dry etching step, the liner film LNA is formed on the first gate electrode positioned in the opening portion of the mask layer MK2. The thickness of the liner film LNA positioned on the first gate electrode and exposed from the opening portion is smaller than the thickness of the liner film LN positioned on the first gate electrode and covered with the insulating film IF3. Therefore, the formation of the voids can be prevented in the step of filling the region between the first gate electrode and the second gate electrode with the interlayer insulating film IL1.

In the foregoing, the invention made by the inventors of the present invention has been concretely described on the basis of the embodiments. However, it is needless to say that the present invention is not limited to the foregoing embodiments, and various modifications can be made within the scope of the present invention.

What is claimed is:

1. A method of manufacturing a semiconductor device comprising steps of:
(a) forming a first gate electrode and a second gate electrode on a main surface of a semiconductor substrate;
(b) forming an impurity region in the semiconductor substrate at a region between the first gate electrode and the second gate electrode;
(c) depositing a first insulating film on the main surface so as to cover the first gate electrode and the second gate electrode;
(d) depositing a second insulating film on the first insulating film;
(e) removing the second insulating film positioned on each of the first gate electrode and the second gate electrode by performing anisotropic dry etching to the second insulating film and thereby exposing the first insulating film, and forming a buried layer that covers the first insulating film and that is made of the second insulating film at the region between the first gate electrode and the second gate electrode;
(f) depositing a third insulating film on the main surface so as to cover the first gate electrode, the second gate electrode, and the buried layer;
(g) forming a contact hole, that penetrates through the third insulating film, the buried layer and the first insulating film, in the third insulating film, the buried layer and the first insulating film at the region between the first gate electrode and the second gate electrode; and
(h) forming a plug electrode electrically connected to the impurity region by forming a conductive layer in the contact hole.

2. The method of manufacturing the semiconductor device according to claim 1,
wherein the step (a) includes steps of:
(a1) depositing a silicon film on the main surface;
(a2) depositing a fourth insulating film on the silicon film; and
(a3) forming the first gate electrode including a first control gate electrode made of the silicon film and a first cap insulating film made of the fourth insulating film and the second gate electrode including a second control gate electrode made of the silicon film and a second cap insulating film made of the fourth insulating film by processing the fourth insulating film and the silicon film.

3. The method of manufacturing the semiconductor device according to claim 2, further comprising, after the step (h), a step of:
(i) forming a wiring layer electrically connected to the plug electrode, on the third insulating film.

4. The method of manufacturing the semiconductor device according to claim 2,
wherein in the step (d), a first thickness of the second insulating film formed at the region between the first gate electrode and the second gate electrode is larger than a second thickness of the second insulating film formed on the first gate electrode.

5. The method of manufacturing the semiconductor device according to claim 2,
wherein the fourth insulating film is made of a first silicon nitride film.

6. The method of manufacturing the semiconductor device according to claim 2,
wherein the first insulating film is made of a second silicon nitride film,
wherein the second insulating film is made of a first silicon oxide film, and
wherein the third insulating film is made of a second silicon oxide film.

7. The method of manufacturing the semiconductor device according to claim 6,
wherein the second insulating film is made of a first O₃-TEOS film, and
wherein the third insulating film is made of a second O₃-TEOS film.

8. A method of manufacturing a semiconductor device comprising steps of:
(a) forming a first gate electrode and a second gate electrode on a main surface of a semiconductor substrate, the first gate electrode having a first sidewall and a second sidewall, and the second gate electrode having a third sidewall and a fourth sidewall;
(b) forming a first memory gate electrode on each of the first sidewall of the first gate electrode and the main surface via a first charge holding film, and forming a second memory gate electrode on each of the fourth sidewall of the second gate electrode and the main surface via a second charge holding film;
(c) forming a first impurity region in the semiconductor substrate at a first region between the first gate electrode and the second gate electrode;
(d) depositing a first insulating film on the main surface so as to cover the first gate electrode, the first memory gate electrode, the second gate electrode, and the second memory gate electrode;
(e) depositing a second insulating film on the first insulating film;
(f) forming a mask layer that covers the first memory gate electrode and the second memory gate electrode and that has an opening portion exposing a first portion of the first gate electrode, the first region, and a second portion of the second gate electrode;
(g) exposing the first insulating film that covers the first portion of the first gate electrode and the second portion of the second gate electrode in the opening portion of the mask layer by performing anisotropic dry etching to the second insulating film, and forming a buried layer that covers the first insulating film and that is made of the second insulating film at the first region;
(h) depositing a third insulating film on the main surface so as to cover the first gate electrode, the second gate electrode and the buried layer;
(i) forming a first contact hole in the third insulating film, the buried layer and the first insulating film at the first region; and
(j) forming a first plug electrode electrically connected to the first impurity region by forming a first conductive layer in the first contact hole,
wherein each of the first gate electrode and the second gate electrode extends in a first direction along the main surface of the semiconductor substrate, and the first gate electrode and the second gate electrode are arranged in a second direction orthogonal to the first direction,
wherein each of the first sidewall and the second sidewall of the first gate electrode extends in the first direction,
wherein the second sidewall of the first gate electrode faces the third sidewall of the second gate electrode, and
wherein each of the third sidewall and the fourth sidewall of the second gate electrode extends in the first direction.

9. The method of manufacturing the semiconductor device according to claim 8,
wherein in the step (a), a third gate electrode having a fifth sidewall and a sixth sidewall and a fourth gate electrode having a seventh sidewall and an eighth sidewall are formed on the main surface,
wherein in the step (b), a third memory gate electrode is formed on each of the sixth sidewall of the third gate electrode and the main surface via a third charge holding film, and a fourth memory gate electrode is formed on each of the seventh sidewall of the fourth gate electrode and the main surface via a fourth charge holding film,
wherein in the step (c), a second impurity region is formed in the semiconductor substrate at a second region between the third memory gate electrode and the fourth memory gate electrode,
wherein in the step (d), the first insulating film is deposited on the main surface so as to cover the third gate electrode, the third memory gate electrode, the fourth gate electrode, the fourth memory gate electrode and the second region,
wherein in the step (f), the mask layer covers the third memory gate electrode, the second region and the fourth memory gate electrode,
wherein in the step (h), the third insulating film covers the second insulating film remaining at the second region, the third memory gate electrode and the fourth memory gate electrode,
wherein in the step (i), a second contact hole is formed in each of the third insulating film, the second insulating film and the first insulating film at the second region,
wherein in the step (j), a second plug electrode electrically connected to the second impurity region is formed by forming a second conductive layer in the second contact hole,
wherein each of the third gate electrode and the fourth gate electrode extends in the first direction of the main surface, and the third gate electrode and the fourth gate electrode are arranged in the second direction,
wherein each of the fifth sidewall and the sixth sidewall of the third gate electrode extends in the first direction,
wherein each of the seventh sidewall and the eighth sidewall of the fourth gate electrode extends in the first direction, and
wherein the sixth sidewall of the third gate electrode faces the seventh sidewall of the fourth gate electrode.

10. The method of manufacturing the semiconductor device according to claim 9,
wherein the step (a) includes steps of:
(a1) depositing a silicon film on the main surface;
(a2) depositing a fourth insulating film on the silicon film; and
(a3) forming the first gate electrode including a first control gate electrode made of the silicon film and a first cap insulating film made of the fourth insulating film, the second gate electrode including a second control gate electrode made of the silicon film and a second cap insulating film made of the fourth insulating film, the third gate electrode including a third control gate electrode made of the silicon film and a third cap insulating film made of the fourth insulating film, and the fourth gate electrode including a fourth control gate electrode made of the silicon film and a fourth cap insulating film made of the fourth insulating film, by processing the fourth insulating film and the silicon film.

11. The method of manufacturing the semiconductor device according to claim 10, further comprising, after the step (j), a step of:
(k) forming a first wiring layer electrically connected to the first plug electrode, on the third insulating film positioned at the first region, and forming a second wiring layer electrically connected to the second plug electrode, on the third insulating film positioned at the second region,
wherein each of the first wiring layer and the second wiring layer extends in the second direction.

12. The method of manufacturing the semiconductor device according to claim 10,
wherein in the step (e), at the first region, a first thickness of the second insulating film is larger than a second thickness of the second insulating film formed on the first gate electrode.

13. The method of manufacturing the semiconductor device according to claim 10,
wherein the fourth insulating film is made of a first silicon nitride film.

14. The method of manufacturing the semiconductor device according to claim 10,
wherein the first insulating film is made of a second silicon nitride film,
wherein the second insulating film is made of a first silicon oxide film, and
wherein the third insulating film is made of a second silicon oxide film.

15. The method of manufacturing the semiconductor device according to claim 14,
wherein the second insulating film is made of a first O₃-TEOS film, and
wherein the third insulating film is made of a second O₃-TEOS film.

16. The method of manufacturing the semiconductor device according to claim 10,
wherein a first distance between the third memory gate electrode and the fourth memory gate electrode is larger than a second distance between the first gate electrode and the second gate electrode.

17. The method of manufacturing the semiconductor device according to claim 8,
wherein in the step (g), a third thickness of the first insulating film that is positioned on each of the first gate electrode and the second gate electrode and that is exposed from the opening portion of the mask layer is smaller than a fourth thickness of the first insulating film covered with the mask layer.
